(19) United States
(12) Patent Application Publication
(10) Pub. No.: US 2023/0205953 A1
(43) Pub. Date: Jun. 29, 2023

(54) MACHINE LEARNING-BASED SYSTEM ARCHITECTURE DETERMINATION

(71) Applicant: Siemens Industry Software NV, Leuven (BE)

(72) Inventors: Janani Venugopalan, Plainsboro, NJ (US); Wesley Reinhart, Boalsburg, PA (US); Lucia Mirabella, Plainsboro, NJ (US); Mike Nicolai, Bierbeek (BE)

(73) Assignee: Siemens Industry Software NV, Leuven (BE)

(21) Appl. No.: 18/000,296

(22) PCT Filed: Jun. 5, 2020
(86) PCT No.: PCT/US2020/036229

§ 371 Date: Nov. 30, 2022

(51) Int. Cl. G06F 30/27

(52) U.S. Cl. CPC G06F 30/27

(57) ABSTRACT

Examples of techniques for machine learning-based system architecture determination are described herein. An aspect includes receiving a system architecture specification corresponding to a system design, and a plurality of topological variants of the system architecture specification. Another aspect includes determining a system architecture graph based on the system architecture specification. Another aspect includes classifying, by a neural network-based classifier, each of the topological variants as a feasible architecture or an infeasible architecture based on the system architecture graph. Another aspect includes identifying a subset of the feasible architectures as system design candidates based on performance predictions.

### BACKGROUND

The present techniques relate to machine learning. More specifically, the techniques relate to machine learning-based system architecture determination.

Human engineers or designers may use their expertise and skills to design system architectures for complex engineering systems. A relatively large number of possible architectures may be generated based on the system architecture, and the possible architectures may be reviewed and to decide on which of the possible architectures are feasible. From the pool of feasible architectures, selected architectures may be further explored and roughly simulated to predict system performance. On the basis of the predicted performance, top performing models (which may be based on one or more particular performance requirements, e.g., higher acceleration for a car suspension) are selected for trade-off studies using high fidelity simulations in order to determine a final optimized design. The trade-off studies may require a relatively large amount of time and effort by an engineering team, and therefore may be performed for a relatively small set of manually created models.

### SUMMARY

Embodiments of the present invention are directed to duplicate code section detection for source code. A non-limiting example computer-implemented method includes receiving a system architecture specification corresponding to a system design, and a plurality of topological variants of the system architecture specification. The method also includes determining a system architecture graph based on the system architecture specification. The method also includes classifying, by a neural network-based classifier, each of the topological variants as a feasible architecture or an infeasible architecture based on the system architecture graph. The method also includes identifying a subset of the feasible architectures as system design candidates based on performance predictions.

Other embodiments of the present invention implement features of the above-described method in computer systems and computer program products.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

FIG. 1 is a block diagram of an example system for machine learning-based system architecture determination;

FIG. 2 is a process flow diagram of an example method for machine learning-based system architecture determination;

FIG. 3A is a block diagram of an example system architecture specification for machine learning-based system architecture determination;

FIG. 3B is a block diagram of example topological variants for machine learning-based system architecture determination;

FIG. 4 is a block diagram of an example system architecture graph for machine learning-based system architecture determination;

FIG. 5 is a block diagram of an example set of graphlets for machine learning-based system architecture determination;

FIG. 6 is a graph illustrating an example saliency map for machine learning-based system architecture determination;

FIG. 7 is a block diagram of an example extracted rule for machine learning-based system architecture determination; and

FIG. 8 is a block diagram of an example computer system for use in conjunction with machine learning-based system architecture determination.

### DETAILED DESCRIPTION

Embodiments of machine learning-based system architecture determination are provided, with exemplary embodiments being discussed below in detail. Development of high-performance functional system models for complex engineering systems, including but not limited to embedded systems, satellite systems, or a suspension system or a powertrain of a vehicle, may require a relatively large amount of time and effort by design engineers. A tool for system architecture design for complex systems may use a combinatorial approach to generate a set of possible designs that need to be refined by expert engineers to determine feasible topologies for the system architecture. The process of refining the possible designs to determine a reduced set of feasible system architectures may require manual review of a relatively large number of possible designs by the expert engineers. As engineers may not be able to manually review the relatively large number of possible designs (e.g., thousands) that may be produced by a system architecture design tool, there may be limited exploration of the design space, and some feasible architectures may not be considered.

Machine learning may be used to discover rules that characterize feasible and infeasible system architecture designs in order to reduce the number of possible designs that need to be reviewed by an engineering team. Classification of possible designs into feasible and infeasible system architectures may be performed based on graph embedding. In various embodiments, the graph embedding may include generation of an adjacency matrix or graphlet-based embedding that is performed based on a system architecture graph. Feasible architectures may be identified for further analysis based on the extracted rules. These feasible architectures are parameterized, and simulations are executed using machine learning techniques to evaluate key performance indicators (KPIs). The KPIs may be determined relatively quickly and accurately using surrogate models. Depending on the requirements of the system and the determined KPIs, a relatively small number of the identified feasible system architectures may be selected for more extensive manual analysis and review.

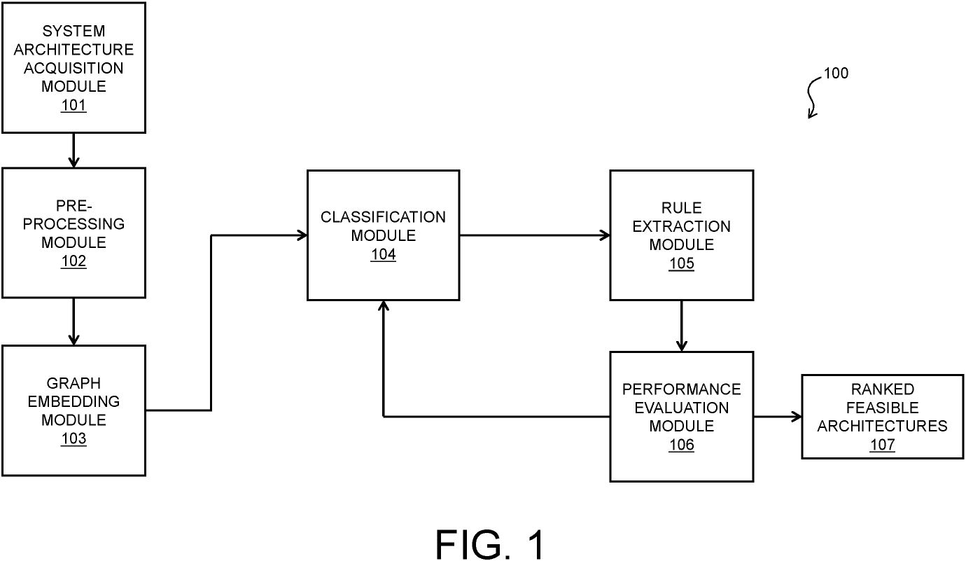

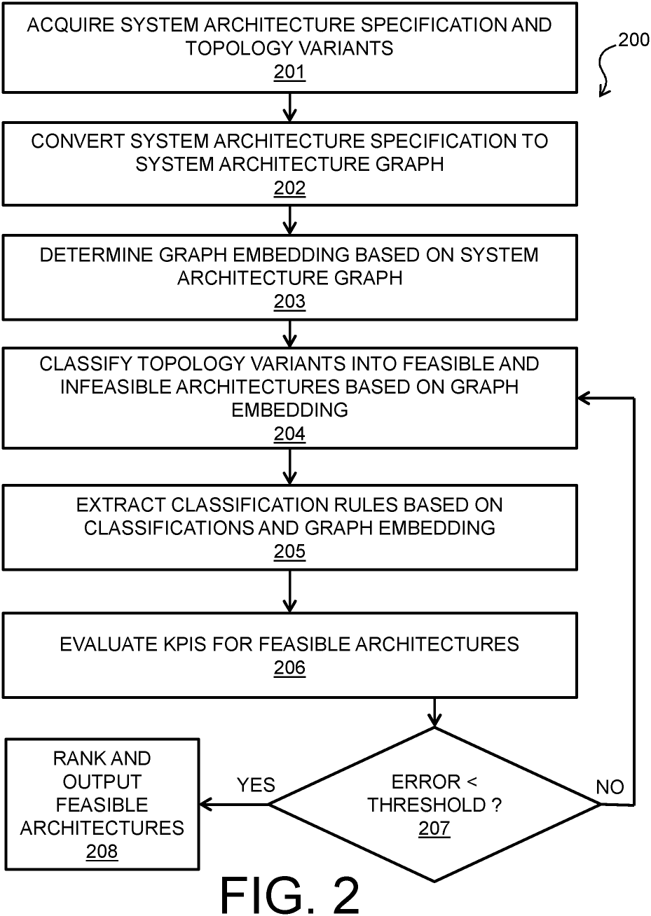

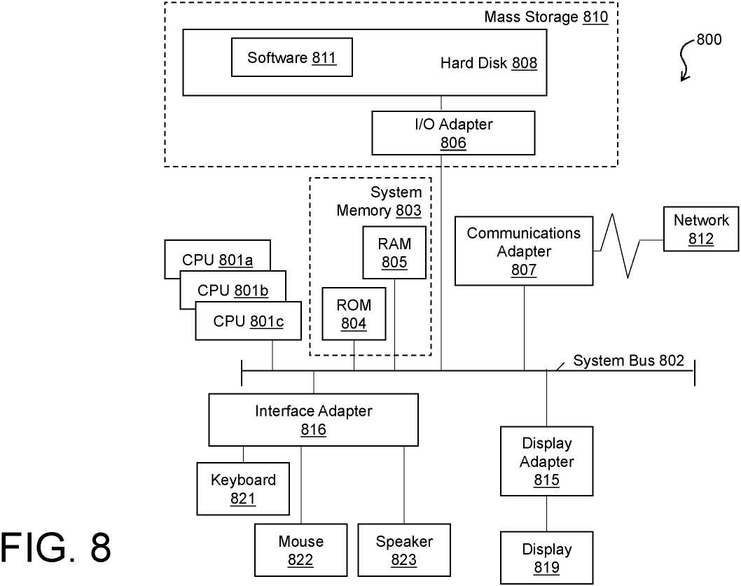

FIG. 1 is a block diagram illustrating a system 100 for machine learning-based system architecture determination in accordance with one or more embodiments of the present invention. FIG. 2 is a process flow diagram of an illustrative method 200 for machine learning-based system architecture determination in accordance with one or more embodiments of the present invention. FIGS. 1 and 2 will be described in conjunction with one another hereinafter. Embodiments of system 100 and method 200 may be implemented in conjunction with any appropriate computer system, such as computer system 800 of FIG. 8. For example, system 100 may include software 811 that is executed by processors 801, and may operate on data stored in system memory 803 and/or mass storage 810.

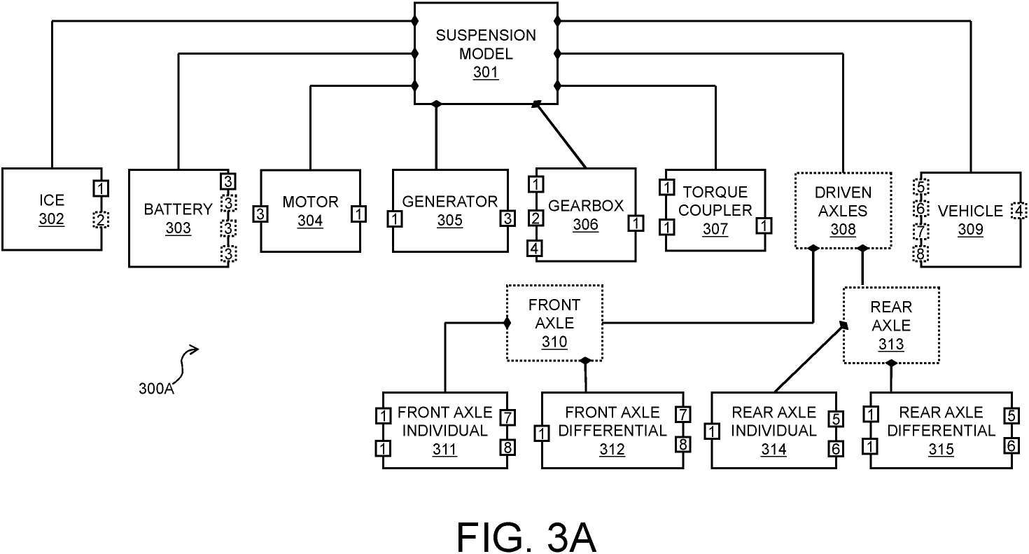

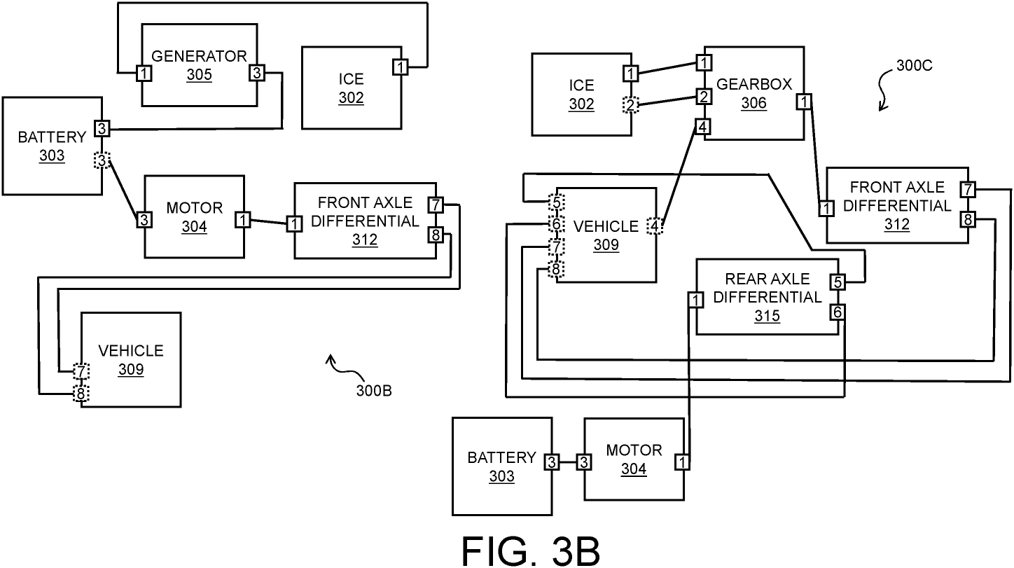

In block 201 of method 200, system architecture acquisition module 101 in system 100 accepts as input a system architecture specification for a complex engineering problem, including possible topological variants, and parameters or configuration options for the elements of the system architecture specification. The system architecture specification may describe any appropriate complex system, including but not limited to an embedded system, a satellite system, and a suspension system or a powertrain of a vehicle. The system architecture specification and topological variants may be determined by a generation engine and/or one or more experts (e.g., engineers) in various embodiments. The system architecture specification may include any appropriate information, such as a list of elements of the system architecture and any possible connections between the elements of the system architecture. In some embodiments, the system architecture specification may include an extensible markup language (XML) document detailing the possible connections between components of the system architecture. The configuration information may include any appropriate types of, and values for, the elements that are included in the system architecture specification. An example of a system architecture specification and topological variants for a vehicle suspension system that may be received by embodiments of a system architecture acquisition module 101 in block 201 are illustrated with respect to FIGS. 3A-B, and example associated configuration options are illustrated with respect to Table 1, which are discussed in further detail below.

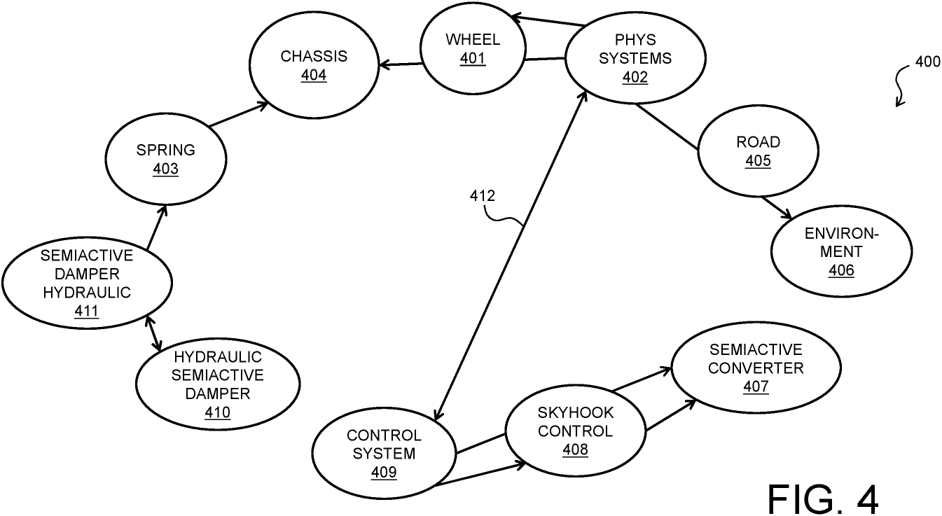

In block 202 of method 200, pre-processing module 102 of system 100 receives the system architecture specification and associated topological variants from system architecture acquisition module 101. The pre-processing module 102 may convert an input format of the system architecture specification (e.g., an XML representation) into a graph structure (e.g., a NetworkX graph), in which each element of the system architecture specification is represented as a node, with the edges between nodes denoting connections. The edges may be directed, and include data on input and output ports on the connected nodes. The output of the pre-processing module 102 is a system architecture graph corresponding to the system architecture specification, which is provided to graph embedding module 103. An example of a system architecture graph that may be generated by pre-processing module 102 is illustrated with respect to FIG. 4, which is discussed in further detail below. In various embodiments, the system architecture specification that is received by the pre-processing module 102, and the system architecture graph that is output by the pre-processing module 102, may each be in any appropriate format.

In block 203 of method 200, graph embedding module 103 receives the system architecture graph from pre-processing module 102. The graph embedding module 103 generates a graph embedding of particular predefined dimensions based on the system architecture graph. The graph embedding may be mapped to sub-structures within the system architecture graph. In some embodiments, an adjacency matrix may be generated by graph embedding module 103 based on the system architecture graph. In some embodiments, graphlet-based embedding may be performed by graph embedding module 103 based on the system architecture graph. The two kinds of embeddings each have a size that is the same irrespective of input graph size, which may facilitate the use of machine learning models for performance prediction by performance evaluation module 106.

One or more embodiments of graph embedding module 103 may generate an adjacency matrix in block 203 that represents how each node in the system architecture graph is connected to each of the other nodes in the input graph. An adjacency matrix may be a sparse matrix representing the connectivity of edges in the system architecture graph. For example, each entry in the adjacency matrix may correspond to two nodes in the system architecture graph, and may describe a connection (i.e., an edge) between the two nodes corresponding to the entry. For example, if there is an edge between two nodes in the system architecture graph, then the corresponding entry for the two nodes in the adjacency matrix may be a one; if there is no connection between two nodes, the entry may be zero. The entries in the adjacency matrix may indicate directional edges in the system architecture graph, e.g., a first entry in the adjacency matrix corresponding to node 1 and node 2 may be one, and a second entry in the adjacency matric corresponding to node 2 and node 1 may be zero, for a system architecture graph including a directional edge from node 1 to node 2. The adjacency matrix may be constructed based on a maximal set of nodes found in the input system architecture graph.

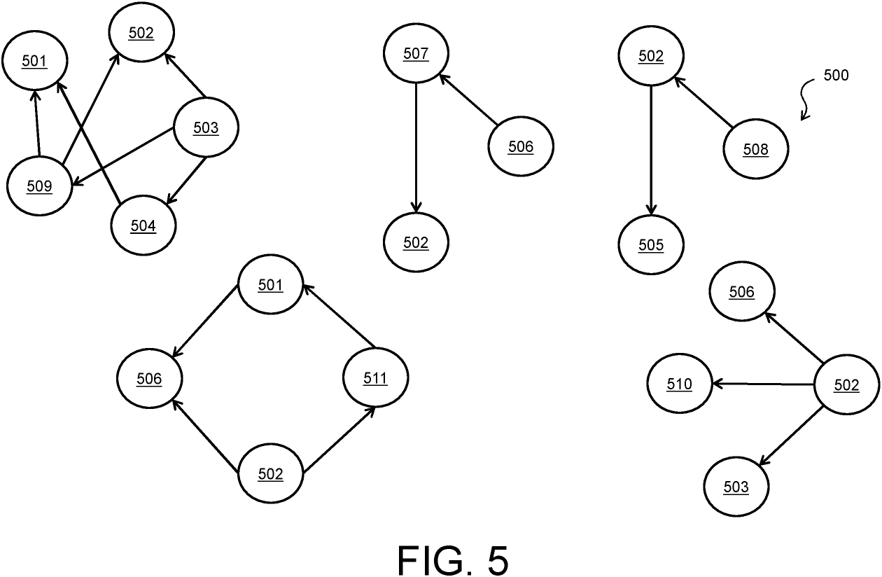

One or more embodiments of graph embedding module 103 may perform graphlet-based embedding in block 203 by generating graphlets from the input system architecture graph, and counting a number of times each specific graphlet was generated. Graphlets are relatively small, connected, non-isomorphic induced subgraphs of the larger network described by the input system architecture graph. In various embodiments, the input system architecture graph that is used to determine the graphlet-based embedding may be an uncolored network or a colored network, and an undirected network or a directed network. Isomorphic graphlets may be filtered from the generated graphlets; isomorphism may be determined based on identities of node and edge attributes, and based on port types. The graphlets contained in the input system architecture graph may be counted using any appropriate algorithm, including but not limited to an orbit counting algorithm (ORCA) and G-Tries. In some embodiments, a histogram of the graphlet frequencies may be generated by graph embedding module 103. The histogram may be provided as a feature vector to classification module 104 in some embodiments, or the graphlet frequencies may be compared to each other using the histogram, e.g., based on a norm difference. In some embodiments, the graphlets may be vectorized by extracting a basis that includes a set of subgraphs. Each graphlet may be represented in terms of the basis set. Any coordinates that have zero variance may be removed from the set of graphlets. An example of a set of graphlets that may be generated using graphlet-based embedding by embodiments of graph embedding module 103 in block 203 is illustrated with respect to FIG. 5, which is discussed in further detail below.

In block 204 of method 200, the classification module 104 receives the graph embedding from the graph embedding module 103, and classifies the topological variants (i.e., possible system architectures) into feasible architectures and infeasible architectures based on the graph embedding. The classification module may include a neural network-based classifier. Any architectures labeled as infeasible architectures by classification module 104 may not be subjected to further review. The classification module 104 may use a Siamese network and contrastive loss to classify the topological variants in some embodiments. The Siamese network outputs may include a vector that may be used to distinguish pairs of topological variants as belonging to the same label or to different labels. In some embodiments, the neural network-based classifier in classification module 104 may include a plurality of layers including a final layer whose values are trained by freezing all the other layers in the neural network-based classifier. The output of the classification module 104 is a labeling of each topological variant of the system architecture as either a feasible architecture or an infeasible architecture.

In block 205 of method 200, rule extraction module 105 receives the possible system architectures, their assigned labels from classification module 104 (e.g., feasible architecture or infeasible architecture), and the trained classifier from classification module 104. The rule extraction module 105 extracts rules that indicate why a possible architecture is feasible or infeasible based on the classifications. A negative rule that is determined by rule extraction module 105 may specify that the absence of a feature indicates that a possible system architecture is feasible or infeasible. For example, a negative rule may correspond to a feature that is absent from the feasible architectures. A positive rule that is determined by rule extraction module 105 may specify that the presence of a feature indicates that a possible system architecture is feasible or infeasible. For example, a negative rule may correspond to a feature that is present in the feasible architectures. An example of a negative feature that is a bad connection may include a connection directly between the road and the motor of a car. Detecting the presence of a bad connection in a possible architecture may indicate that the possible architecture is an infeasible architecture; detecting the absence of this connection in a possible architecture may indicate that the possible architecture is a feasible architecture.

In some embodiments, saliency maps may be generated based on the classified architectures by rule extraction module 105. A negative saliency map may detect the absence of key features for each label (e.g., the absence of bad connections in feasible architectures, or the absence of good connections in infeasible architectures). A positive saliency map may detect the presence of key features for each label (e.g., the presence of bad connections in infeasible architectures, or the presence of good connections in feasible architectures). In some embodiments, a positive saliency map (indicating the presence of one or more features) and a negative saliency map (indicating the absence of one or more features) may be generated for both the set of infeasible architectures and for the set of feasible architectures. Combining the negative saliency map constructed based on the feasible architectures and the positive saliency map constructed based on infeasible architectures may give a set of rules that characterize infeasible architectures. Combining the negative saliency map constructed based on the infeasible architectures and the positive saliency map constructed based on feasible architectures may give a set of rules that characterize feasible architectures. Each of the saliency maps may be converted into a binary representation using thresholding in some embodiments. Most prominent portions of the binary representations may be detected by rule extraction module 105 for use as rules. Gradient-weighted class activation mapping (GradCAM++) may be used to determine portions of the saliency maps that are responsible for the classification of the architectures into a given label (i.e., feasible or infeasible) by the classifier. GradCAM++ may be used to extract classification rules from the saliency maps by rule extraction module 105. The Gradcam map may highlight any portions of the saliency map that are responsible for the label.

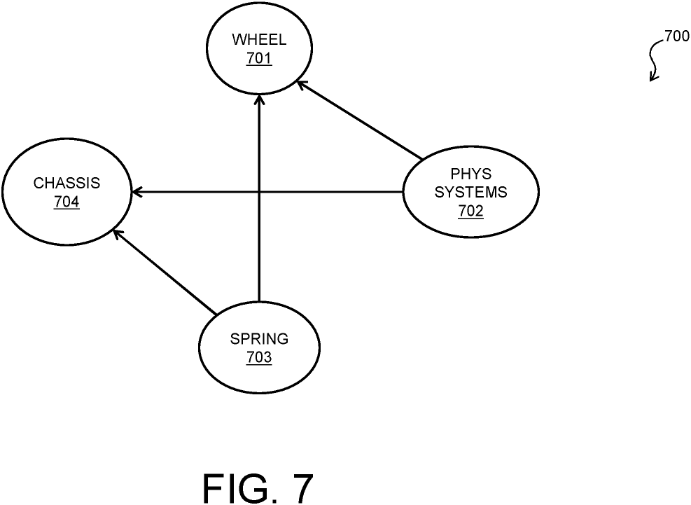

A rule may be represented in various formats by rule extraction module 105 in various embodiments, based on whether the graph embedding module 103 generated an adjacency matrix or performed graphlet-based embedding. The extracted rules may be fed back into the neural network-based classifier in classification module 104 to refine the filtering of the possible architectures into feasible and infeasible architectures. An example of a rule that may be generated by rule extraction module 105 for infeasible architectures in an embodiment in which the graph embedding module 103 performs graphlet-based embedding is illustrated with respect to FIG. 7, which is discussed in further detail below. Example rules for infeasible architectures for an embodiment in which the graph embedding module 103 generates an adjacency matrix may include:

{‘Environment’ is connected to ‘Semiactive_damper_hydraulic’} and
{‘Environment’ is connected to ‘balance_control’}

In block 206 of method 200, performance evaluation module 106 receives the classified set of feasible architectures, the graph embedding, and the configuration options. The performance evaluation module constructs a surrogate model that performs simulations of the feasible architectures based on the configuration options that were received with the system architecture specification, and determines KPIs that measure predicted performance for each feasible architecture. The KPIs may include any appropriate metric that may describe the system architecture, including but not limited to acceleration, fuel consumption, cost, availability, and weight. Any appropriate number of data points may be used by the performance evaluation module 106 to predict any appropriate number of KPIs for the feasible architectures.

The performance evaluation module 106 may use one or more regression approaches in various embodiments. Examples of regression approaches that may be implemented in embodiments of performance evaluation module 106 include, but are not limited to, random forest regression, linear regression, gradient boosted regression, extra trees regression, residual neural network-based regression, extremely randomized trees regression, and Gaussian process regression. The performance evaluation module 106 may be trained using results from initial runs of reduced order simulations until a desired error rate is achieved (e.g., an error rate of less than 5%). In some embodiments, the error metric may be 100*abs(y_{pred}-yₜᵣᵤₑ)/abs(yₜᵣᵤₑ), where y_{pred} is the values predicted by the surrogate model, and yₜᵣᵤₑ is the true values (e.g., ground truth) found in a test data set of known results for the same set of inputs.

In block 207 of method 200, it is determined whether the error rate of the KPI predictions from the performance evaluation module 106 is less than a threshold. Based on the error being greater than the threshold in block 207, the performance evaluation module 106 may identify any incorrectly classified architectures, and flow may return to block 204, in which the neural network-based classifier in classification module 104 may be refined based on the identified incorrectly classified architectures, and the possible architectures may be reclassified as feasible or infeasible based on the refined classification module 104. Flow may then proceed through blocks 205, in which rules are extracted based on the classifications, and block 206, in which the KPIs and associates error rates are determined for the reclassified architectures. Flow then proceeds from block 206 to block 207. Based on the error being less than the threshold in block 207, flow proceeds to block 208. In block 208, the current set of feasible architectures may be ranked based on the KPIs that were determined by the performance evaluation module 106 in block 206, and the ranked feasible architectures 107 are output by performance evaluation module 106 of system 100. A subset of the ranked feasible architectures 107 may be selected as candidates for further analysis and manual review by design engineers in order to select a final architecture for the design of the complex system. The complex system may be built according to the selected final architecture.

It is to be understood that the block diagram of FIG. 1 is not intended to indicate that the system 100 is to include all of the components shown in FIG. 1. Rather, the system 100 can include any appropriate fewer or additional components not illustrated in FIG. 1 (e.g., additional computer systems, processors, memory components, embedded controllers, modules, computer networks, network interfaces, data inputs, etc.). Further, the embodiments described herein with respect to system 100 may be implemented with any appropriate logic, wherein the logic, as referred to herein, can include any suitable hardware (e.g., a processor, an embedded controller, or an application specific integrated circuit, among others), software (e.g., an application, among others), firmware, or any suitable combination of hardware, software, and firmware, in various embodiments.

The process flow diagram of FIG. 2 is not intended to indicate that the operations of the method 200 are to be executed in any particular order, or that all of the operations of the method 200 are to be included in every case. Additionally, the method 200 can include any suitable number of additional operations.

FIG. 3A illustrates an example system architecture specification 300A for machine learning-based system architecture determination in accordance with one or more embodiments of the present invention. The system architecture specification 300A corresponds to a suspension model 301 of a vehicle, and includes a plurality of elements 302-315. As shown in system architecture specification 300A, the suspension model 301 includes internal combustion engine 302, battery 303, electric motor 304, generator 305, gearbox 306, torque coupler 307, driven axles 308, which includes a front axle 310 with a front axle individual 311 and front axle differential 312, a rear axle 313 including a rear axle individual 314 and a rear axle differential 315, and a vehicle 309. Elements 302-315 include specified connection points that may connect to other connection points of the same type on other elements in various topological variants of the system architecture specification 300A. For example, internal combustion engine (ICE) 301 has a first connection point of type 1 and a second connection point of type 2; the first connection point may connect to any other connection point of type 1 (e.g., on electric motor 304, generator 305, gearbox 306, or torque coupler 307). The system architecture specification 300A may be generated by an engineering team, and may be provided to system architecture acquisition module 101 of system 100 of FIG. 1 in block 201 of method 200 of FIG. 2.

A set of configuration options corresponding to the system architecture specification may also be received in block 201 of method 200; an example of such configuration options corresponding to system architecture specification 300A is illustrated with respect to Table 1. The configuration options may give possible values for various elements of the system architecture specification, and may be used by performance evaluation module 106 to determine KPIs for feasible architectures.

TABLE 1

Example Configuration Options for System Architecture Specification

| | | |
|---|---|---|
| Element | Number of Options | Values |
| ICE | 3 | 1.5 liters (L) |
| | | 2.0 L |
| | | 1.4 L |
| Electric motor | 3 | 96 kilowatts (kW), 250 newton-meters (Nm) |
| | | 96 kW, 250 Nm |
| | | 96 kW, 250 Nm |
| Battery | 1 | 96 cells, 20 amp-hours (Ah) |
| Shaft and Wheels | 1 | Final gear: 3.68 |
| Vehicle | 1 | 195/50R20(F) |
| | | 215/45R20 (R) |
| | | 1560 kilograms (kg) |
| | | C_{d}: 0.26 |
| | | S: 2.11 meters squared (m²) |

FIG. 3A is shown for illustrative purposes only. In various embodiments, a system architecture specification such as is illustrated in FIG. 3A may include any appropriate number and type of elements, each having any appropriate number and type of connection points, and may correspond to any appropriate type of complex system.

FIG. 3B illustrates topological variants 300B-C for machine learning based system architecture determination in accordance with one or more embodiments of the present invention. Topological variants 300B-C are generated based on system architecture specification 300A by, for example, a generation engine, and are received by system architecture acquisition module 101 in block 201 of FIG. 2. Topological variants 300B-C each include a subset of the elements 302-305 from system architecture specification 300A connected in a manner that conforms to the restraints of the system architecture specification 300A (e.g., connection points of the same type are connected between elements). A relatively large number (e.g., hundreds or thousands) of topological variants such as topological variants 300B-C may be generated based on a system architecture specification such as system architecture specification 300A; the total set of topological variants may include any variants that are allowed within the restraints defined by the system architecture specification 300A. The topological variants such as topological variants 300B-C are sorted by classification module 104 of FIG. 1 into feasible and infeasible architectures in block 204 of FIG. 2.

FIG. 3B is shown for illustrative purposes only. Any appropriate number of topological variants such as topological variants 300B-C may be generated based on a system architecture specification 300A. Further, a topological variant such as topological variants 300B-C may include any appropriate number of elements of any appropriate type, and the elements may be connected in any appropriate manner.

FIG. 4 illustrates an example system architecture graph 400 for machine learning-based system architecture determination in accordance with one or more embodiments of the present invention. The system architecture graph 400 includes a plurality of interconnected nodes 401-411. As shown in FIG. 4, system architecture graph 400 includes wheel 401, physical system 402, spring 403, chassis 404, road 405, environment 406, semiactive converter 407, skyhook control 408, control system 409, hydraulic semiactive damper 410, and semiactive damper hydraulic 411. The nodes 401- 411 are connected by edges. The edges may be directed, and include data on input and output ports on the connected nodes 401-411 (e.g., edge 412 from an output port on control system 409 to an input port on physical systems 402). A system architecture graph such as system architecture graph 400 may be generated by pre-processing module 102 of system 100 of FIG. 1 based on a system architecture specification such as system architecture specification 300A of FIG. 3A. The system architecture graph 400 is input to graph embedding module 103 to determine a graph embedding corresponding to the system architecture specification upon which the system architecture graph 400 was based in block 203 of method 200 of FIG. 2.

FIG. 4 is shown for illustrative purposes only. A system architecture graph such as system architecture graph 400 may include any appropriate number of nodes of any appropriate type, and the nodes may be connected in any appropriate manner by any appropriate number and configuration of edges.

FIG. 5 illustrates an example set of graphlets 500 for machine learning-based system architecture determination in accordance with one or more embodiments of the present invention. The set of graphlets 500 may be generated in by graph embedding module 103 in block 203 of method 200 of FIG. 2 based on a system architecture graph such as system architecture graph 400 of FIG. 4. Graphlets 500 each include a subset of interconnected nodes 501-511 from a base system architecture graph.

FIG. 5 is shown for illustrative purposes only. A set of graphlets such as graphlets 500 may each include any appropriate number of nodes of any appropriate type, and the nodes may be connected in any appropriate manner. Further, any appropriate number of graphlets such as graphlets 500 may be generated based on a system architecture graph.

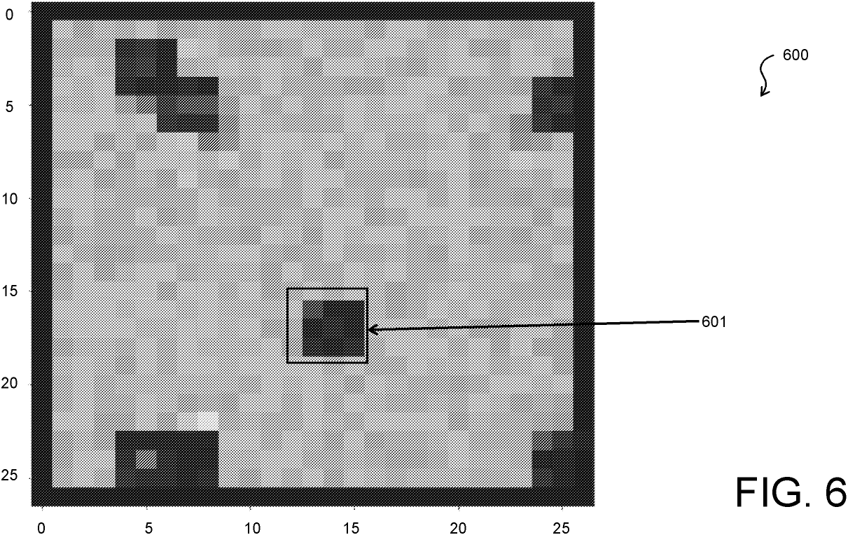

FIG. 6 illustrates an example saliency map 600 for machine learning-based system architecture determination in accordance with one or more embodiments of the present invention. A saliency map such as saliency map 600 may be generated by rule extraction module 105 of FIG. 1 in block 205 of FIG. 2 based on an adjacency matrix, which may be received from graph embedding module 103. The saliency map 600 of FIG. 6 is a negative saliency map, which indicates that the absence of a feature, corresponding to area 601 in the saliency map, is responsible for topological variants that lack the feature being classified as feasible or infeasible by classification module 104. For example, area 601 of the saliency map 600 may correspond to an absence of a connection (e.g., road is connected to hydraulic_passive_damper) between two specified nodes in the topological variants that causes the topological variants that do not include this connection to be classified as feasible by classification module 104.

FIG. 6 is shown for illustrative purposes only. For example, a saliency map such as saliency map 600 may include any appropriate data and features, and may include a negative saliency map, positive saliency map, or a gradient weighted class activation map in various embodiments.

FIG. 7 illustrates an example extracted rule 700 for machine learning-based system architecture determination in accordance with one or more embodiments of the present invention. Rule 700 may be determined by rule extraction module 105 of FIG. 1 in block 205 of FIG. 2 based on graphlet-based embedding that was performed by graph embedding module 103. Rule 700 includes a set of interconnected nodes 701-704, and defines particular connections between the nodes that may be required for a particular topological variant to be classified as an infeasible architecture. The connections in a rule may be directional. For example, in rule 700, wheel 701 and chassis 704 are both acted upon by physical systems 702 and spring 703.

FIG. 7 is shown for illustrative purposes only. For example, a rule such as rule 700 may include any appropriate number and type of nodes connected in any appropriate manner, and may be a positive or negative rule in various embodiments.

Turning now to FIG. 8, a computer system 800 is generally shown in accordance with an embodiment. The computer system 800 can be an electronic, computer framework comprising and/or employing any number and combination of computing devices and networks utilizing various communication technologies, as described herein. The computer system 800 can be easily scalable, extensible, and modular, with the ability to change to different services or reconfigure some features independently of others. The computer system 800 may be, for example, a server, desktop computer, laptop computer, tablet computer, or smartphone. In some examples, computer system 800 may be a cloud computing node. Computer system 800 may be described in the general context of computer system executable instructions, such as program modules, being executed by a computer system. Generally, program modules may include routines, programs, objects, components, logic, data structures, and so on that perform particular tasks or implement particular abstract data types. Computer system 800 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 8, the computer system 800 has one or more central processing units (CPU(s)) 801a, 801b, 801c, etc. (collectively or generically referred to as processor(s) 801). The processors 801 can be a single-core processor, multi-core processor, computing cluster, or any number of other configurations. The processors 801, also referred to as processing circuits, are coupled via a system bus 802 to a system memory 803 and various other components. The system memory 803 can include a read only memory (ROM) 804 and a random access memory (RAM) 805. The ROM 804 is coupled to the system bus 802 and may include a basic input/output system (BIOS), which controls certain basic functions of the computer system 800. The RAM is read-write memory coupled to the system bus 802 for use by the processors 801. The system memory 803 provides temporary memory space for operations of said instructions during operation. The system memory 803 can include random access memory (RAM), read only memory, flash memory, or any other suitable memory systems.

The computer system 800 comprises an input/output (I/O) adapter 806 and a communications adapter 807 coupled to the system bus 802. The I/O adapter 806 may be a small computer system interface (SCSI) adapter that communicates with a hard disk 808 and/or any other similar component. The I/O adapter 806 and the hard disk 808 are collectively referred to herein as a mass storage 810.

Software 811 for execution on the computer system 800 may be stored in the mass storage 810. The mass storage 810 is an example of a tangible storage medium readable by the processors 801, where the software 811 is stored as instructions for execution by the processors 801 to cause the computer system 800 to operate, such as is described herein below with respect to the various Figures. Examples of computer program product and the execution of such instruction is discussed herein in more detail. The communications adapter 807 interconnects the system bus 802 with a network 812, which may be an outside network, enabling the computer system 800 to communicate with other such systems. In one embodiment, a portion of the system memory 803 and the mass storage 810 collectively store an operating system, which may be any appropriate operating system to coordinate the functions of the various components shown in FIG. 8.

Additional input/output devices are shown as connected to the system bus 802 via a display adapter 815 and an interface adapter 816 and. In one embodiment, the adapters 806, 807, 815, and 816 may be connected to one or more I/O buses that are connected to the system bus 802 via an intermediate bus bridge (not shown). A display 819 (e.g., a screen or a display monitor) is connected to the system bus 802 by a display adapter 815, which may include a graphics controller to improve the performance of graphics intensive applications and a video controller. A keyboard 821, a mouse 822, a speaker 823, etc. can be interconnected to the system bus 802 via the interface adapter 816, which may include, for example, a Super I/O chip integrating multiple device adapters into a single integrated circuit. Suitable I/O buses for connecting peripheral devices such as hard disk controllers, network adapters, and graphics adapters typically include common protocols, such as the Peripheral Component Interconnect (PCI). Thus, as configured in FIG. 8, the computer system 800 includes processing capability in the form of the processors 801, and, storage capability including the system memory 803 and the mass storage 810, input means such as the keyboard 821 and the mouse 822, and output capability including the speaker 823 and the display 819.

In some embodiments, the communications adapter 807 can transmit data using any suitable interface or protocol, such as the internet small computer system interface, among others. The network 812 may be a cellular network, a radio network, a wide area network (WAN), a local area network (LAN), or the Internet, among others. An external computing device may connect to the computer system 800 through the network 812. In some examples, an external computing device may be an external webserver or a cloud computing node.

It is to be understood that the block diagram of FIG. 8 is not intended to indicate that the computer system 800 is to include all of the components shown in FIG. 8. Rather, the computer system 800 can include any appropriate fewer or additional components not illustrated in FIG. 8 (e.g., additional memory components, embedded controllers, modules, additional network interfaces, etc.). Further, the embodiments described herein with respect to computer system 800 may be implemented with any appropriate logic, wherein the logic, as referred to herein, can include any suitable hardware (e.g., a processor, an embedded controller, or an application specific integrated circuit, among others), software (e.g., an application, among others), firmware, or any suitable combination of hardware, software, and firmware, in various embodiments.

Although specific embodiments of the disclosure have been described, one of ordinary skill in the art will recognize that numerous other modifications and alternative embodiments are within the scope of the disclosure. For example, any of the functionality and/or processing capabilities described with respect to a particular system, system component, device, or device component may be performed by any other system, device, or component. Further, while various illustrative implementations and architectures have been described in accordance with embodiments of the disclosure, one of ordinary skill in the art will appreciate that numerous other modifications to the illustrative implementations and architectures described herein are also within the scope of this disclosure. In addition, it should be appreciated that any operation, element, component, data, or the like described herein as being based on another operation, element, component, data, or the like may be additionally based on one or more other operations, elements, components, data, or the like. Accordingly, the phrase “based on,” or variants thereof, should be interpreted as “based at least in part on.”

The present disclosure may be a system, a method, apparatus, and/or a computer program product. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user’s computer, partly on the user’s computer, as a stand-alone software package, partly on the user’s computer and partly on a remote computer or entirely on the remote computer or server. In the latter scenario, the remote computer may be connected to the user’s computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, apparatus, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present techniques have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method comprising:
receiving, by a processor, a system architecture specification corresponding to a system design, and a plurality of topological variants of the system architecture specification;
determining a system architecture graph based on the system architecture specification;
classifying, by a neural network-based classifier, each of the topological variants as a feasible architecture or an infeasible architecture based on the system architecture graph; and
identifying a subset of the feasible architectures as system design candidates based on performance predictions.

2. The method of claim 1, wherein identifying the subset of the feasible architectures as system design candidates based on performance predictions comprises:
determining key performance indicators (KPIs) for the feasible architectures based on configuration options corresponding to the system architecture specification; and
ranking the feasible architectures based on the KPIs.

3. The method of claim 1, further comprising:
determining a graph embedding based on the system architecture graph, wherein the classifying is performed based on the graph embedding.

4. The method of claim 3, wherein determining the graph embedding comprises constructing an adjacency matrix based on the system architecture graph.

5. The method of claim 3, wherein determining the graph embedding comprises performing graphlet-based embedding based on the system architecture graph.

6. The method of claim 1, further comprising extracting classification rules based on the classification of each of the topological variants as a feasible architecture or an infeasible architecture, wherein extracting the classification rules comprises:
constructing a saliency map based on a subset of the classified topological variants; and
identifying a feature in the saliency map based on gradient-weighted class activation mapping (GradCAM++).

7. The method of claim 6, wherein the feature corresponds to one of a negative rule, wherein the feature is absent from the subset of the classified topological variants corresponding to the saliency map, and a positive rule, wherein the feature is present in the subset of the classified topological variants corresponding to the saliency map.

8. A system comprising:
a memory having computer readable instructions; and
one or more processors for executing the computer readable instructions, the computer readable instructions controlling the one or more processors to perform operations comprising:
receiving a system architecture specification corresponding to a system design, and a plurality of topological variants of the system architecture specification;
determining a system architecture graph based on the system architecture specification;
classifying, by a neural network-based classifier, each of the topological variants as a feasible architecture or an infeasible architecture based on the system architecture graph; and
identifying a subset of the feasible architectures as system design candidates based on performance predictions.

9. The system of claim 8, wherein identifying the subset of the feasible architectures as system design candidates based on performance predictions comprises:
determining key performance indicators (KPIs) for the feasible architectures based on configuration options corresponding to the system architecture specification; and
ranking the feasible architectures based on the KPIs.

10. The system of claim 8, further comprising:
determining a graph embedding based on the system architecture graph, wherein the classifying is performed based on the graph embedding.

11. The system of claim 10, wherein determining the graph embedding comprises constructing an adjacency matrix based on the system architecture graph.

12. The system of claim 10, wherein determining the graph embedding comprises performing graphlet-based embedding based on the system architecture graph.

13. The system of claim 8, further comprising extracting classification rules based on the classification of each of the topological variants as a feasible architecture or an infeasible architecture, wherein extracting the classification rules comprises:
constructing a saliency map based on a subset of the classified topological variants; and
identifying a feature in the saliency map based on gradient-weighted class activation mapping (GradCAM++).

14. The system of claim 13, wherein the feature corresponds to one of a negative rule, wherein the feature is absent from the subset of the classified topological variants corresponding to the saliency map, and a positive rule, wherein the feature is present in the subset of the classified topological variants corresponding to the saliency map.

15. A computer program product comprising a computer readable storage medium having program instructions embodied therewith, the program instructions executable by a processor to cause the processor to perform operations comprising:
receiving a system architecture specification corresponding to a system design, and a plurality of topological variants of the system architecture specification;
determining a system architecture graph based on the system architecture specification;
classifying, by a neural network-based classifier, each of the topological variants as a feasible architecture or an infeasible architecture based on the system architecture graph; and
identifying a subset of the feasible architectures as system design candidates based on performance predictions.

16. The computer program product of claim 15, wherein identifying the subset of the feasible architectures as system design candidates based on performance predictions comprises:
determining key performance indicators (KPIs) for the feasible architectures based on configuration options corresponding to the system architecture specification; and
ranking the feasible architectures based on the KPIs.

17. The computer program product of claim 15, further comprising:
determining a graph embedding based on the system architecture graph, wherein the classifying is performed based on the graph embedding.

18. The computer program product of claim 17, wherein determining the graph embedding comprises constructing an adjacency matrix based on the system architecture graph.

19. The computer program product of claim 17, wherein determining the graph embedding comprises performing graphlet-based embedding based on the system architecture graph.

20. The computer program product of claim 15, further comprising extracting classification rules based on the classification of each of the topological variants as a feasible architecture or an infeasible architecture, wherein extracting the classification rules comprises:
constructing a saliency map based on a subset of the classified topological variants; and
identifying a feature in the saliency map based on gradient-weighted class activation mapping (GradCAM++).
